(19) United States
(12) Patent Application Publication
(10) Pub. No.: US 2009/0170304 A1
(43) Pub. Date: Jul. 2, 2009

(54) METHOD OF MANUFACTURING SEMICONDUCTOR DEVICE

(75) Inventors: Yoichiro Tarui, Tokyo (JP); Kenichi Ohtsuka, Tokyo (JP); Yosuke Suzuki, Tokyo (JP); Katsuomi Shiozawa, Tokyo (JP); Kyozo Kanamoto, Tokyo (JP); Toshiyuki Oishi, Tokyo (JP); Yasunori Tokuda, Tokyo (JP); Tatsuo Omori, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: MITSUBISHI ELECTRIC CORPORATION, Tokyo (JP)

(21) Appl. No.: 12/337,878

(22) Filed: Dec. 18, 2008

(30) Foreign Application Priority Data
Dec. 27, 2007 (JP) 2007-335698

(51) Int. Cl. H01L 21/441

(52) U.S. Cl. 438/608; 438/660; 438/685; 438/686; 257/E21.477

(57) ABSTRACT

A method of manufacturing a semiconductor device is provided, which can reduce the contact resistance of an ohmic electrode to a p-type nitride semiconductor layer and can achieve long-term stable operation. In forming, in an electrode forming step, a p-type ohmic electrode of a metal film by successive lamination of a Pd film which is a first p-type ohmic electrode and a Ta film which is a second p-type ohmic electrode on a p-type GaN contact layer, the metal film is formed to include an oxygen atom. In the presence of an oxygen atom in the metal film, then in a heat-treatment step, the p-type ohmic electrode of the metal film is heat-treated in an atmosphere that contains no oxygen atom-containing gas.

### BACKGROUND OF THE INVENTION

1. Field of the Invention

The present invention relates to a method of manufacturing a semiconductor device, and more specifically, to a method of manufacturing a semiconductor device which method is suitably used for forming an ohmic electrode on a p-type layer in a nitride semiconductor device.

2. Description of the Background Art

One of the challenges for semiconductor devices using a nitride semiconductor such as gallium nitride (GaN), aluminum gallium nitride (AlGaN), or indium gallium nitride (InGaN) is to form a low-resistance ohmic electrode on a p-type nitride semiconductor layer. In particular, for semiconductor lasers or other semiconductor devices that operate at high current densities, it is absolutely necessary to provide an ohmic electrode with stability on a p-type nitride semiconductor layer to achieve long-term stable operation.

National publication of translation No. 2007-518260 has suggested performing heat treatment in an atmosphere containing oxygen after the formation of an ohmic electrode, whereby gallium (Ga) in a nitride semiconductor layer diffuses to the outside, forming Ga holes, which will then serve as acceptors to increase the hole concentration, thus reducing the contact resistance.

Japanese Patent Application Laid-open No. 10-209493 has suggested forming an ohmic electrode of palladium (Pd) or the like and then performing heat treatment in an atmosphere containing oxygen, which will reduce the contact resistance of the ohmic electrode.

When heat treatment is performed in an atmosphere containing oxygen in order to reduce the contact resistance of an ohmic electrode to a p-type nitride semiconductor layer, a metallic oxide will be formed on the surface of the ohmic electrode. Since metallic oxides are of high resistance, semiconductor lasers or other semiconductor devices that operate at high current densities have the problem that they cannot operate with stability for a long period of time because long-term operation will produce heat, increasing the contact resistance of an ohmic electrode in proportion to time. To solve the above problem, it is necessary to reduce the contact resistance of an ohmic electrode to a p-type nitride semiconductor layer and not to form a metallic oxide on the surface of the ohmic electrode.

### SUMMARY OF THE INVENTION

It is an object of the present invention to provide a method of manufacturing a semiconductor device that can reduce the contact resistance of an ohmic electrode to a p-type nitride semiconductor layer and can achieve long-term stable operation.

A method of manufacturing a semiconductor device according to the invention includes an electrode forming step and a heat-treatment step. In the electrode forming step, a palladium (Pd) film and a tantalum (Ta) film is formed in succession on a p-type contact layer of a nitride semiconductor to form an ohmic electrode of a metal film of the palladium (Pd) film and the tantalum (Ta) film. The electrode forming step is performed in such a manner that the metal film is formed to include an oxygen atom. In the heat-treatment step, the ohmic electrode is heat-treated in an atmosphere not containing an oxygen atom-containing gas.

The above method of manufacturing a semiconductor device reduces the contact resistance of the ohmic electrode to the p-type contact layer, thereby producing a semiconductor device that will produce no heat even if operating at high current densities, thus achieving long-term stable operation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a state after an epitaxial-growth step;

FIG. 2 is a cross-sectional view illustrating a state after the formation of a ridge structure;

FIG. 3 is a cross-sectional view illustrating a state after the formation of an insulation film 9;

FIG. 4 is a cross-sectional view illustrating a state after the formation of a first p-type ohmic electrode 10;

FIG. 5 is a cross-sectional view illustrating a state after the formation of a second p-type ohmic electrode 1;

FIG. 6 is a cross-sectional view illustrating a state after the formation of a pad electrode 12; and

FIG. 7 is a cross-sectional view illustrating a structure of a semiconductor device 20.

### DESCRIPTION OF THE PREFERRED EMBODIMENTS

### First Preferred Embodiment

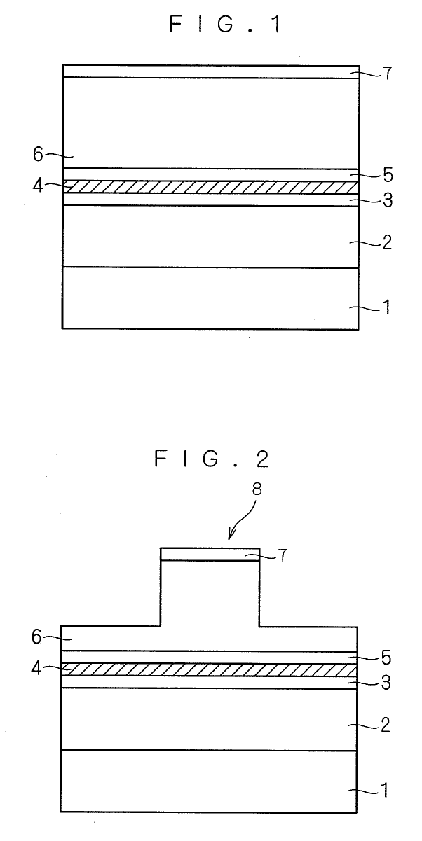

FIGS. 1 to 7 are cross-sectional views illustrating the state in the method of manufacturing a gallium-nitride (GaN)-based semiconductor device 20 according to a first preferred embodiment of the invention. FIG. 1 is a cross-sectional view illustrating a state after an epitaxial-growth step. In the epitaxial-growth step, as shown in FIG. 1, an n-type aluminum-gallium-nitride (AlGaN) cladding layer 2 for use in carrier and optical confinement, an n-type GaN guide layer 3 for use in optical propagation, an indium-gallium-nitride (InGaN) quantum-well active layer 4 which is a light-emitting area, a p-type GaN guide layer 5 for use in light propagation, a p-type AlGaN cladding layer 6 for use in carrier and optical confinement, and a p-type GaN contact layer 7 for use in establishment of p-type contact are epitaxially grown in succession on an n-type low-resistance GaN substrate 1 by, for example, MOCVD (metal organic chemical vapor deposition).

The n-type GaN guide layer 3 may alternatively be an n-type InGaN guide layer. The p-type GaN guide layer 5 may alternatively be a p-type InGaN guide layer. The p-type GaN contact layer 7 is doped with magnesium (Mg) as an acceptor at concentrations of 1×10¹⁹/cm³ or more.

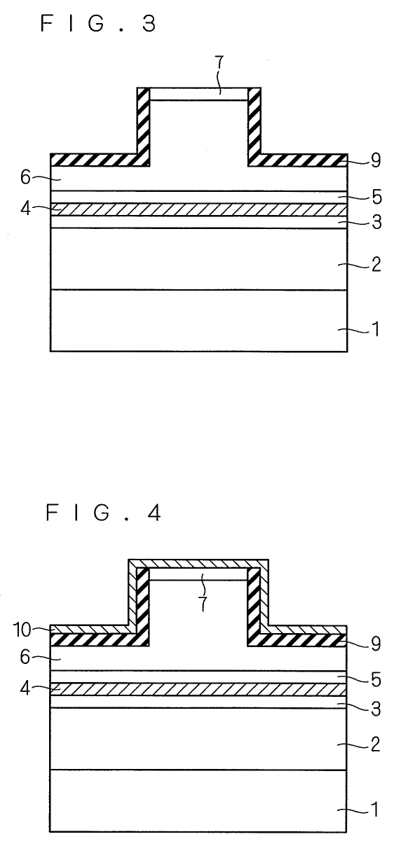

FIG. 2 is a cross-sectional view illustrating a state after the formation of a ridge structure. After the completion of the aforementioned epitaxial-growth step, then in a ridge-structure forming step, an etching mask is formed on the top of the p-type GaN contact layer 7 where a ridge 8 will be formed, i.e., where a p-type ohmic electrode will be formed (which area is hereinafter referred to also as a “p-type electrode forming area”). The etching mask is formed of, for example, a resist. Forming the etching mask in this way and dry-etching the surface up to the p-type AlGaN cladding layer 6 produces a ridge structure as shown in FIG. 2.

FIG. 3 is a cross-sectional view illustrating a state after the formation of an insulation film 9. After the formation of the ridge structure in FIG. 2, then in an insulation-film forming step, the insulation film 9 is formed, as shown in FIG. 3, on the side face of the ridge 8 and on the surface of the p-type AlGaN cladding layer 6 other than the ridge 8, i.e., in the area other than the p-type electrode forming area. The insulation film 9 is formed by, for example, lift-off. More specifically, leaving the etching mask used for forming the ridge structure in FIG. 2, the insulation film 9 is formed by any one of the following: CVD (chemical vapor deposition), vacuum evaporation, and sputtering. The insulation film 9 may, for example, be a silicon oxide (SiOₓ) film such as a silicon dioxide (SiO₂) film formed to a thickness of 0.2 μm. By removing the insulation film 9 on the top of the ridge 8 with removal of the etching mask, the insulation film 9 can exist in the area other than the p-type electrode forming area. This insulation film 9 has the function of passing current to only the ridge 8 and the function of controlling a light distribution in the ridge 8 by its film thickness, permittivity, or index of refraction.

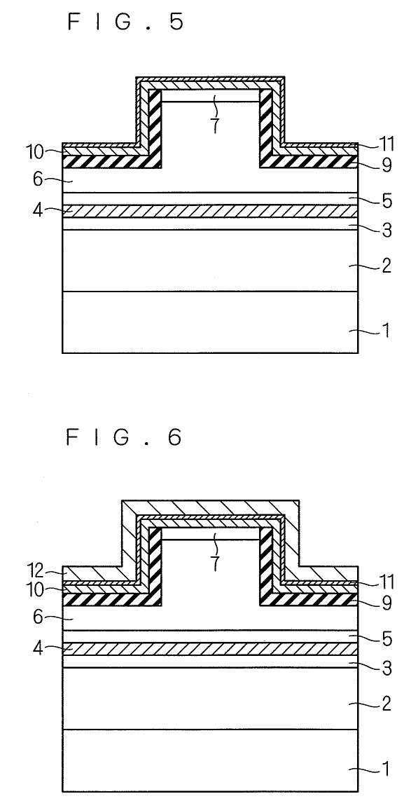

FIG. 4 is a cross-sectional view illustrating a state after the formation of a first p-type ohmic electrode 10, and FIG. 5 is a cross-sectional view illustrating a state after the formation of a second p-type ohmic electrode 11. After the formation of the insulation film 9 in FIG. 3, then in an electrode forming step, the first p-type ohmic electrode 10 is formed on the top of the p-type GaN contact layer 7 and on the surface of the insulation film 9 as shown in FIG. 4, and then the second p-type electrode 11 is formed on the surface of the first p-type ohmic electrode 10 as shown in FIG. 5. This successive formation of the first p-type ohmic electrode 10 and the second p-type ohmic electrode 11 on the p-type GaN contact layer 7 produces a p-type ohmic electrode. In a subsequent heat-treatment step, the first and second p-type ohmic electrodes 10 and 11 are heat-treated at heat-treatment temperatures from 400 to 700° C. in an atmosphere not containing an oxygen atom-containing gas, specifically in a gaseous atmosphere not containing an oxygen atom, e.g., an atmosphere of an inert gas such as nitrogen or argon, or in a vacuum. This reduces the contact resistance of the first p-type ohmic electrode 10 to the p-type GaN contact layer 7. The electrode forming step of forming the first and second p-type ohmic electrodes 10 and 11 will be described later in detail.

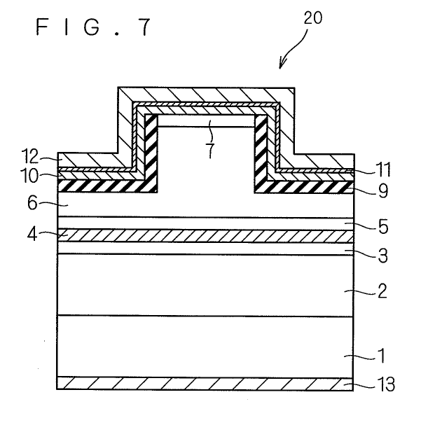

FIG. 6 is a cross-sectional view illustrating a state after the formation of a pad electrode 12. After the heat treatment of the first and second p-type ohmic electrodes 10 and 11 described above, then in a pad-electrode forming step, the pad electrode 12 is formed on the surface of the second p-type ohmic electrode 11 as shown in FIG. 6. Specifically, the pad electrode 12 has, for example, a Ti—Ta—Ti—Au four-layer structure in which a titanium (Ti) film, a tantalum (Ta) film, another Ti film, and a gold (Au) film are formed in order of mention on the second p-type ohmic electrode 11. Alternatively, the pad electrode 12 may have a Ti—Mo—Ti—Au four-layer structure in which a Ti film, a molybdenum (Mo) film, another Ti film, and an Au film are formed in order of mention on the second p-type ohmic electrode 11.

FIG. 7 is a cross-sectional view illustrating the structure of the semiconductor device 20. After the formation of the pad electrode 12, then in a layer thinning step, the surface of the n-type low-resistance GaN substrate 1 opposite the surface thereof where the n-type AlGaN cladding layer 2 is formed is polished to about 100 μm as shown in FIG. 7. Then, in an n-type-electrode forming step, an n-type ohmic electrode 13 is formed on the polished surface. This completes a wafer process including the epitaxial-growth step, the ridge-structure forming step, the insulation-film forming step, the electrode forming step, the heat-treatment step, the pad-electrode forming step, the layer thinning step, and the n-type-electrode forming step. Specifically, the n-type ohmic electrode 13 has, for example, a Ti—Pt—Au three-layer structure in which a Ti film, a platinum (Pt) film, and an Au film are formed in order of mention on the surface of the n-type low-resistance GaN substrate 1 opposite the surface thereof where the n-type AlGaN cladding layer 2 is formed.

After the wafer process, the subsequent steps, such as forming a resonator by cleavage, forming an end-coating film through the formation of a single- or multi-layer dielectric or metal film with desired reflectivity on a cleavage plane, and isolation assembly with individual isolation of elements, will complete the manufacture of the semiconductor device 20.

Now, the electrode forming step is described. In the electrode forming step, firstly by vacuum evaporation, a palladium (Pd) film is deposited to a thickness of about 50 nm as the first p-type ohmic electrode 10. After the deposition of the Pd film, an oxygen atom-containing gas such as oxygen (O₂), ozone (O₃), dinitrogen monoxide (N₂O), or nitrogen monoxide (NO) is supplied into an evaporation chamber to oxidize the surface of the Pd film, thereby taking in oxygen into the Pd film. The evaporation chamber is then evacuated again, and by vacuum evaporation, a tantalum (Ta) film is deposited to a thickness of about 20 nm as the second p-type ohmic electrode 11. The Pd film is necessary for establishing an ohmic contact with the p-type GaN contact layer 7, and the Ta film is necessary for inhibiting cohesion and promoting the ohmic properties of the Pd film during the heat treatment which will be described later.

After a series of works of depositing the Pd film and the Ta film in a single vacuum evaporator, then in the heat-treatment step, the first and second p-type ohmic electrodes 10 and 11 are heat-treated at heat-treatment temperatures from 400 to 700° C. in an atmosphere not containing an oxygen atom-containing gas, specifically in a gaseous atmosphere not containing an oxygen atom, e.g., an atmosphere of an inert gas such as nitrogen or argon, or in a vacuum. This reduces the contact resistance of the first p-type ohmic electrode 10 to the p-type GaN contact layer 7.

If, in taking in oxygen into the Pd film, the temperature of the n-type low-resistance GaN substrate 1, on which the Pd film is formed, is raised to a temperature of 100 to 300° C., the amount of oxygen taken into the Pd film will increase, which further reduces the contact resistance of the first p-type ohmic electrode 10 to the p-type GaN contact layer 7 after the heat treatment. This temperature increase may be accomplished simultaneously with the supply of an oxygen atom-containing gas or may be after the supply and stop of an oxygen atom-containing gas and after evacuation.

According to the method of manufacturing a semiconductor device described in the first preferred embodiment of the invention, in the electrode forming step, a metal film that forms a p-type ohmic electrode of the Pd film, which is the first p-type ohmic electrode 10, and the Ta film, which is the second p-type ohmic electrode 11, on the p-type GaN contact layer 7 is formed to include an oxygen atom. To be more specific, the Pd film which is the first p-type ohmic electrode 10 is formed to include an oxygen atom. Specifically speaking, after the deposition of the Pd film, an oxygen atom-containing gas is supplied into the evaporation chamber to oxidize the surface of the Pd film, thereby completing the formation of the Pd film. Thus, oxygen atoms are taken into the Pd film which is the first p-type ohmic electrode 10, which in turn results in the oxygen atoms being taken into the metal film which forms the p-type ohmic electrode.

In the presence of oxygen atoms in the metal film, the p-type ohmic electrode of the metal film is heat-treated in the heat-treatment step. Thus, even if the heat treatment is performed in an atmosphere not containing an oxygen atom-containing gas, the oxygen atoms in the metal film, more specifically, the oxygen atoms in the Pd film which is the first p-type ohmic electrode 10, will induce outward diffusion of gallium (Ga) in the p-type GaN contact layer 7, thereby forming Ga holes. Those Ga holes then serve as acceptors to increase the hole concentration, thus reducing the contact resistance of the first p-type ohmic electrode 10 to the p-type GaN contact layer 7 and accordingly reducing the contact resistance of the p-type ohmic electrode to the p-type GaN contact layer 7.

Since the p-type ohmic electrode is heat-treated in an atmosphere not containing an oxygen atom-containing gas, no metal oxide film is formed on the surface of the second p-type ohmic electrode 11, i.e., on the surface of the p-type ohmic electrode. Hence, there is no high-resistance film formed in the metal film which forms the p-type ohmic electrode, which allows the production of the semiconductor device 20 that will produce no heat even if operating at high current densities, thus achieving long-term stable operation.

Since in the present preferred embodiment, the metal film forming the p-type ohmic electrode is formed of a Pd film and a Ta film, the contact resistance of the p-type ohmic electrode to the p-type GaN contact layer 7 can be reduced more than in the case where the metal film is formed of any other material.

In the method of manufacturing a semiconductor device according to the present preferred embodiment, there is no oxygen supply after the deposition of the Ta film which is the second p-type ohmic electrode 11, so that the Ta film is formed in an atmosphere not containing an oxygen atom-containing gas. In other words, the Ta film is formed not to include an oxygen atom. Since the Ta film which is the second p-type ohmic electrode 11 includes no oxygen atom as described above, oxidation of the Ta film during the above heat treatment performed in an atmosphere not containing an oxygen atom-containing gas is more reliably prevented, which results in more reliable prevention of the formation of a high-resistance metal oxide film, such as a Ta oxide film, on the surface of the second p-type ohmic electrode 11, i.e., on the surface of the p-type ohmic electrode. This more reliably prevents the formation of a high-resistance film in the p-type ohmic electrode, thus allowing more reliable production of the semiconductor device 20 that will produce no heat even if operating at high current densities, thus achieving long-term stable operation.

### Second Preferred Embodiment

Next is described a method of manufacturing a semiconductor device according to a second preferred embodiment of the invention. The method of manufacturing a semiconductor device according to the present preferred embodiment is similar to that previously described in the first preferred embodiment, and differs in only the electrode forming step of forming the first and second p-type ohmic electrodes 10 and 11. The following description is thus given of the electrode forming step different from that in the first preferred embodiment, and corresponding parts to those previously described in the first preferred embodiment are referred to by the same reference numerals to eliminate redundant descriptions of the common parts.

In the electrode forming step according to the present preferred embodiment, firstly by vacuum evaporation, a first Pd film is deposited to a thickness of about 20 nm as the first p-type ohmic electrode 10 on the p-type GaN contact layer 7. After the deposition of the first Pd film, an oxygen atom-containing gas such as oxygen (O₂), ozone (O₃), dinitrogen monoxide (N₂O), or nitrogen monoxide (NO) is supplied into the evaporation chamber to oxidize the surface of the first Pd film, thereby taking in oxygen into the first Pd film. The evaporation chamber is then evacuated again, and by vacuum evaporation, a second Pd film is deposited to a thickness of about 30 nm as the first p-type ohmic electrode 10 on the first Pd film. In this way, the first p-type ohmic electrode 10 is formed of the first and second Pd films. Then, a Ta film is deposited to a thickness of about 20 nm as the second p-type ohmic electrode 11.

The thickness of each film forming the first p-type ohmic electrode 10, i.e., the first and second Pd films, is determined so that the first p-type ohmic electrode 10 is equal in thickness to that in the first preferred embodiment. The first and second Pd films are necessary for establishing an ohmic contact with the p-type GaN contact layer 7, and the Ta film is necessary for inhibiting cohesion and promoting the ohmic properties of the first and second Pd films during the heat treatment which will be described later.

After a series of works of depositing the first and second Pd films and the Ta film in a single vacuum evaporator, then, as in the first preferred embodiment, in the heat-treatment step, the first and second p-type ohmic electrodes 10 and 11 are heat-treated at heat-treatment temperatures from 400 to 700° C. in an atmosphere not containing an oxygen atom-containing gas, specifically, in a gaseous atmosphere not containing an oxygen atom, e.g., an atmosphere of an inert gas such as nitrogen or argon, or in a vacuum. This reduces the contact resistance of the first p-type ohmic electrode 10 to the p-type GaN contact layer 7.

If, in taking in oxygen into the first Pd film, the temperature of the n-type low-resistance GaN substrate 1, on which the first Pd film is formed, is raised to a temperature of 100 to 300° C., the amount of oxygen taken into the first Pd film will increase, which further reduces the contact resistance of the first p-type ohmic electrode 10 to the p-type GaN contact layer 7 after the heat treatment. This temperature increase may be accomplished simultaneously with the supply of an oxygen atom-containing gas or may be after the supply and stop of an oxygen atom-containing gas and after evacuation.

According to the method of manufacturing a semiconductor device described in the present preferred embodiment, the first Pd film forming the first p-type ohmic electrode 10 is formed to include an oxygen atom. To be more specific, after the deposition of the first Pd film, an oxygen atom-containing gas is supplied into the evaporation chamber to oxidize the surface of the first Pd film, thereby completing the formation of the first Pd film. Thus, oxygen atoms are taken into the first Pd film, which in turn results in the oxygen atoms being taken into the first p-type ohmic electrode 10. In other words, oxygen atoms are taken into the metal film forming the p-type ohmic electrode. Thus, even if heat treatment is performed in an atmosphere not containing an oxygen atom-containing gas, the oxygen atoms in the first p-type ohmic electrode 10 will induce outward diffusion of Ga in the p-type GaN contact layer 7, thereby forming Ga holes. Those Ga holes then serve as acceptors to increase the hole concentration, thus reducing the contact resistance of the first p-type ohmic electrode 10 to the p-type GaN contact layer 7.

Besides, because there is no oxygen supply after the deposition of the Ta film which is the second p-type ohmic electrode 11 and because the heat treatment is performed in an atmosphere not containing an oxygen atom-containing gas, no metal oxide film is formed during the heat treatment. In particular, since the second Pd film in contact with the Ta film includes no oxygen, oxidation of the Ta film can be prevented with more reliability than in the first preferred embodiment. This more reliably prevents the formation of a high-resistance film in the p-type ohmic electrode, thus allowing more reliable production of a semiconductor device that will produce no heat even if operating at high current densities, thus achieving long-term stable operation.

### Third Preferred Embodiment

Next is described a method of manufacturing a semiconductor device according to a third preferred embodiment of the invention. The method of manufacturing a semiconductor device according to the present preferred embodiment is similar to that previously described in the first preferred embodiment, and differs in only the electrode forming step of forming the first and second p-type ohmic electrodes 10 and 11. The following description is thus given of the electrode forming step different from that in the first preferred embodiment, and corresponding parts to those previously described in the first preferred embodiment are referred to by the same reference numerals to eliminate redundant descriptions of the common parts.

While the electrode forming step in the first preferred embodiment uses vacuum evaporation for the formation of the first and second p-type ohmic electrodes 10 and 11, the electrode forming step according to the present preferred embodiment uses sputtering for the formation of the first and second p-type ohmic electrodes 10 and 11. To be more specific, firstly by sputtering, a Pd film is deposited to a thickness of about 50 nm as the first p-type ohmic electrode 10. After the deposition of the Pd film, an oxygen atom-containing gas such as such as oxygen (O₂), ozone (O₃), dinitrogen monoxide (N₂O), or nitrogen monoxide (NO) is supplied into a sputter chamber to oxidize the surface of the Pd film, thereby taking in oxygen into the Pd film. Alternatively, the supply of an oxygen atom-containing gas may produce the state of plasma. The sputter chamber is then evacuated again, and by sputtering, a Ta film is deposited to a thickness of about 20 nm as the second p-type ohmic electrode 11.

After a series of works of depositing the Pd film and the Ta film in a single sputtering apparatus, then, as in the first preferred embodiment, in the heat-treatment step, the first and second p-type ohmic electrodes 10 and 11 are heat-treated at heat-treatment temperatures from 400 to 700° C. in an atmosphere not containing an oxygen atom-containing gas, specifically, in a gaseous atmosphere not containing an oxygen atom, e.g., an atmosphere of an inert gas such as nitrogen or argon, or in a vacuum. This reduces the contact resistance of the first p-type ohmic electrode 10 to the p-type GaN contact layer 7.

If, in taking in oxygen into the Pd film, the temperature of the n-type low-resistance GaN substrate 1, on which the Pd film is formed, is raised to a temperature of 100 to 300° C., the amount of oxygen taken into the Pd film will increase, which further reduces the contact resistance of the first p-type ohmic electrode 10 to the p-type GaN contact layer 7 after the heat treatment. This temperature increase may be accomplished simultaneously with the supply of an oxygen atom-containing gas or may be after the supply and stop of an oxygen atom-containing gas and after evacuation.

According to the method of manufacturing a semiconductor device described in the present preferred embodiment, in the electrode forming step, a metal film that forms a p-type ohmic electrode of the Pd film, which is the first p-type ohmic electrode 10, and the Ta film, which is the second p-type ohmic electrode 11, on the p-type GaN contact layer 7 is formed to include an oxygen atom. To be more specific, the Pd film which is the first p-type ohmic electrode 10 is formed to include an oxygen atom. Specifically speaking, after the deposition of the Pd film, an oxygen atom-containing gas is supplied into the sputter chamber to oxidize the surface of the Pd film, thereby completing the formation of the Pd film. Thus, oxygen atoms are taken into the Pd film which is the first p-type ohmic electrode 10, which in turn results in the oxygen atoms being taken into the metal film which forms the p-type ohmic electrode.

In the presence of oxygen atoms in the metal film, the p-type ohmic electrode of the metal film is heat-treated in the heat-treatment step. Thus, even if the heat treatment is performed in an atmosphere not containing an oxygen atom-containing gas, the oxygen atoms in the metal film, more specifically, the oxygen atoms in the Pd film which is the first p-type ohmic electrode 10, will induce outward diffusion of gallium (Ga) in the p-type GaN contact layer 7, thereby forming Ga holes. Those Ga holes then serve as acceptors to increase the hole concentration, thus reducing the contact resistance of the first p-type ohmic electrode 10 to the p-type GaN contact layer 7 and accordingly reducing the contact resistance of the p-type ohmic electrode to the p-type GaN contact layer 7.

Since the p-type ohmic electrode is heat-treated in an atmosphere not containing an oxygen atom-containing gas, no metal oxide film is formed on the surface of the second p-type ohmic electrode 11, i.e., on the surface of the p-type ohmic electrode. Thus, there is no high-resistance film formed in the metal film which is the p-type ohmic electrode, which allows the production of a semiconductor device that will produce no heat even if operating at high current densities, thus achieving long-term stable operation.

In the method of manufacturing a semiconductor device according to the present preferred embodiment, there is no oxygen supply after the deposition of the Ta film which is the second p-type ohmic electrode 11, so that the Ta film is formed in an atmosphere not containing an oxygen atom-containing gas. In other words, the Ta film is formed not to include an oxygen atom. Since the Ta film which is the second p-type ohmic electrode 11 includes no oxygen atom as described above, oxidation of the Ta film during the above heat treatment performed in an atmosphere not containing an oxygen atom-containing gas is more reliably prevented, which results in more reliable prevention of the formation of a high-resistance metal oxide film, such as a Ta oxide film, on the surface of the second p-type ohmic electrode 11, i.e., on the surface of the p-type ohmic electrode. This more reliably prevents the formation of a high-resistance film in the p-type ohmic electrode, thus allowing more reliable production of a semiconductor device that will produce no heat even if operating at high current densities, thus achieving long-term stable operation.

### Fourth Preferred Embodiment

Next is described a method of manufacturing a semiconductor device according to a fourth preferred embodiment of the invention. The method of manufacturing a semiconductor device according to the present preferred embodiment is similar to those previously described in the first and second preferred embodiments, and differs in only the electrode forming step of forming the first and second p-type ohmic electrodes 10 and 11. The following description is thus given of the electrode forming step different from those in the first and second preferred embodiments, and corresponding parts to those previously described in the first and second preferred embodiments are referred to by the same reference numerals to eliminate redundant descriptions of the common parts.

While the electrode forming steps in the first and second preferred embodiments use vacuum evaporation for the formation of the first and second p-type ohmic electrodes 10 and 11, the electrode forming step according to the present preferred embodiment uses sputtering for the formation of the first and second p-type ohmic electrodes 10 and 11. Specifically, firstly by sputtering, a first Pd film is deposited to a thickness of about 20 nm as the first p-type ohmic electrode 10 on the p-type GaN contact layer 7. After the deposition of the first Pd film, an oxygen atom-containing gas such as oxygen (O₂), ozone (O₃), dinitrogen monoxide (N₂O), or nitrogen monoxide (NO) is supplied into a sputter chamber to oxidize the surface of the first Pd film, thereby taking in oxygen into the first Pd film. Alternatively, the supply of an oxygen-atom-containing gas may produce the state of plasma. The chamber is then evacuated again, and by sputtering, a second Pd film is deposited to a thickness of about 30 nm as the first p-type ohmic electrode 10 on the first Pd film. In this way, the first p-type ohmic electrode 10 is formed of the first and second Pd films. Then, a Ta film is deposited to a thickness of about 20 nm as the second p-type ohmic electrode 11.

After a series of works of depositing the first and second Pd films and the Ta film in a single sputtering apparatus, then, as in the first and second preferred embodiments, in the heat-treatment step, the first and second p-type ohmic electrodes 10 and 11 are heat-treated at heat-treatment temperatures from 400 to 700° C. in an atmosphere not containing an oxygen atom-containing gas, specifically, in a gaseous atmosphere not containing an oxygen atom, e.g., an atmosphere of an inert gas such as nitrogen or argon, or in a vacuum. This reduces the contact resistance of the first p-type ohmic electrode 10 to the p-type GaN contact layer 7.

If, in taking in oxygen into the first Pd film, the temperature of the n-type low-resistance GaN substrate 1, on which the first Pd film is formed, is raised to a temperature of 100 to 300° C., the amount of oxygen taken into the first Pd film will increase, which further reduces the contact resistance of the first p-type ohmic electrode 10 to the p-type GaN contact layer 7 after the heat treatment. This temperature increase may be accomplished simultaneously with the supply of an oxygen atom-containing gas or may be after the supply and stop of an oxygen atom-containing gas and after evacuation.

According to the method of manufacturing a semiconductor device described in the present preferred embodiment, since the first Pd film which forms the first p-type ohmic electrode 10 is formed by oxidation of its surface after deposition, oxygen atoms are taken into the first Pd film, which in turn results in the oxygen atoms being taken into the first p-type ohmic electrode 10. Thus, even if the heat treatment is performed in an atmosphere not containing an oxygen atom-containing gas, the oxygen atoms in the first p-type ohmic electrode 10 will induce outward diffusion of Ga in the p-type GaN contact layer 7, thereby forming Ga holes. Those Ga holes then serve as acceptors to increase the hole concentration, thus reducing the contact resistance of the first p-type ohmic electrode 10 to the p-type GaN contact layer 7.

Besides, because there is no oxygen supply after the deposition of the Ta film which is the second p-type ohmic electrode 11 and because the heat treatment is performed in an atmosphere not containing an oxygen atom-containing gas, no metal oxide film is formed during the heat treatment. In particular, since the second Pd film in contact with the Ta film includes no oxygen, oxidation of the Ta film can be prevented with more reliability than in the first preferred embodiment. This more reliably prevents the formation of a high-resistance film in the p-type ohmic electrode, thus allowing more reliable production of a semiconductor device that will produce no heat even if operating at high current densities, thus achieving long-term stable operation.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device comprising:
an electrode forming step of forming a palladium (Pd) film and a tantalum (Ta) film in succession on a p-type contact layer of a nitride semiconductor to form an ohmic electrode of a metal film of said palladium (Pd) film and said tantalum (Ta) film, said electrode forming step being performed in such a manner that said metal film is formed to include an oxygen atom; and
a heat-treatment step of heat-treating said ohmic electrode in an atmosphere that contains no oxygen atom-containing gas.

2. The method of manufacturing a semiconductor device according to claim 1, wherein
in said electrode forming step,
said palladium (Pd) film is formed to include an oxygen atom, and
said tantalum (Ta) film is formed in an atmosphere that contains no oxygen atom-containing gas.

3. The method of manufacturing a semiconductor device according to claim 2, wherein
said palladium (Pd) film is formed of first and second palladium (Pd) films, and
in said electrode forming step,
said first palladium (Pd) film is formed on said p-type contact layer to include an oxygen atom, and said second palladium (Pd) film is formed on said first palladium (Pd) film in an atmosphere that contains no oxygen atom-containing gas.
